(19) United States
(12) Patent Application Publication
(10) Pub. No.: US 2004/0124486 A1
(43) Pub. Date: Jul. 1, 2004

(54) Image sensor adapted for reduced component chip scale packaging

(76) Inventor: Katsumi Yamamoto, Shanghai (CN)

Correspondence Address: PERKINS COIE LLP, PATENT-SEA, P.O. BOX 1247, SEATTLE, WA, 98111-1247, US

(21) Appl. No.: 10/330,824

(22) Filed: Dec. 26, 2002

(51) Int. Cl. H01L 31/0203; H01L 23/34

(52) U.S. Cl. 257/433; 257/728

(57) ABSTRACT

The present invention discloses an image sensor die that has structures intended to more efficiently package the image sensor die. The structures include a spacer ring and stack bumps. The spacer ring serves to support a glass lid over the pixel array of the image sensor die. The stack bumps are raised in order to facilitate direct connection to flexible tape or a printed circuit board.

### TECHNICAL FIELD OF THE INVENTION

The present invention is related to image sensing integrated circuits, and more particularly, to a simplified chip scale package for image sensors.

### BACKGROUND INFORMATION

Image sensors are now extensively used in many applications ranging from cell phone cameras, PC cameras, digital still cameras, and security cameras. Most of these applications require that the image sensor withstand varying environmental conditions. Because of this, chip package solutions for image sensors have been developed to protect the image sensor from environmental factors.

A prior art structure is shown in FIG. 1 in exploded isometric view. FIG. 2 shows the structure of FIG. 1 in assembled cross-section view. The chip package includes a substrate 101 that has incorporated a lead frame. The image sensor 103 is adhered to the substrate 101. The lead frame is then wire bonded to contact pads on the image sensor 103. A cap or spacer 105 is then secured to the lead frame in order to provide spacing between a glass lid 107 and the image sensor 103. The glass lid 107 is required to allow transparent optical imaging by the image sensor 103 to the outside world. Additionally, the glass lid 107 and the spacer 105 serve to prevent environmental contaminants from affecting the operation of the image sensor 103.

The lead frame/substrate 101 provides a means by which signals can be read out from the image sensor 103. In one conventional prior art configuration, the substrate is a ceramic substrate and thus referred to as a ceramic package. Examples of various types of packaging techniques for image sensor are shown in U.S. Patent Application Publication No. 2002/0079438 to Lin, U.S. Patent Application Publication No. 2002/0140072 to Chiu, U.S. Patent Application Publication No. 2002/0148946 to Tu et al., and U.S. Patent Application Publication No. 2002/0006687 to Lam. In each of these disclosures, multiple components are required to mount the image sensor onto a substrate and protect the image sensor with a glass lid.

However, the use of so many components increases the cost of packaging. Therefore, it is desirable to decrease the packaging costs for image sensors.

### BRIEF DESCRIPTION OF THE DRAWINGS

FIG. 1 is a prior art chip scale packaging technique for image sensor integrated circuits.

FIG. 2 is a cross-section view of the prior art structure of FIG. 1 that has been assembled.

FIG. 3 is a top view of an image sensor die formed in accordance with the prior art.

FIG. 4 is a cross-section of the image sensor die of FIG. 3 taken along line A-A′.

FIG. 5 is a top view of an image sensor die formed in accordance with the present invention.

FIG. 6 is a cross-section of the image sensor die of FIG. 5 taken along line B-B′.

FIG. 7 is an image sensor die formed in accordance with the present invention with a glass lid attached.

FIG. 9 shows an image sensor die of the present invention mounted onto a flexible tape.

### DETAILED DESCRIPTION

In the following description, numerous specific details are provided to provide a thorough understanding of the embodiments of the invention. One skilled in the relevant art will recognize, however, that the invention can be practiced without one or more of the specific details, or with other methods, components, etc. In other instances, well-known structures or operations are not shown or described in detail to avoid obscuring aspects of various embodiments of the invention.

Reference throughout the specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout the specification are not necessarily all referring to the same embodiment. Furthermore, the particular features, structures, or characteristics may be combined in any suitable manner in one or more embodiments.

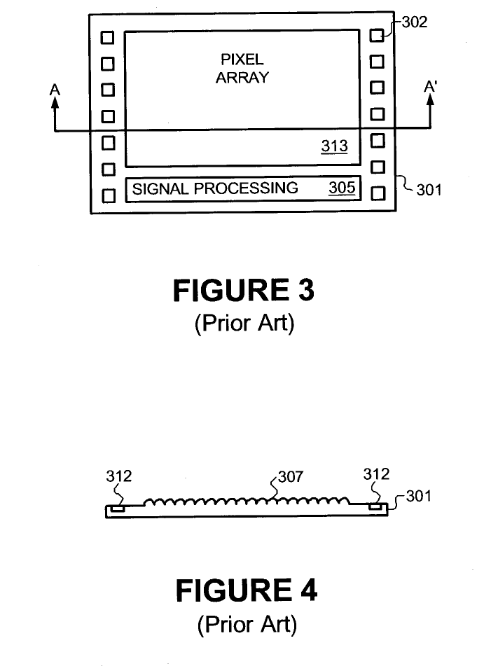

In accordance with the present invention, an image sensor is formed that includes structures on the image sensor die that aid in simplifying the packaging of the image sensor die. FIG. 3 shows a prior art image sensor die 301 that includes a pixel array 303 and a signal processing block 305. Both the pixel array 303 and the signal processing block 305 are formed on the die 301. Other circuitry (such as input/output buffers, drivers, and other components) are typically present on the die 301, but are not shown to avoid obscuring the present invention.

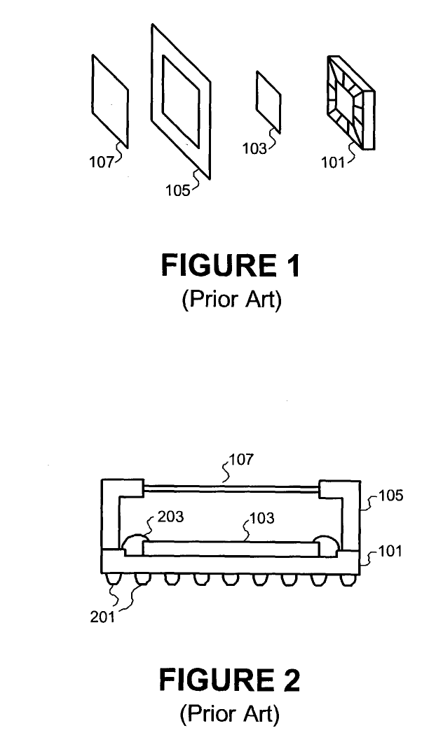

A cross-section taken along line A-A′ is shown in FIG. 4. The image sensor die 301 includes microlenses 307 that are formed atop of each pixel in the pixel array. The microlenses 307 are present to aid in increasing the fill factor of each pixel. Also shown in FIGS. 3 and 4 are bonding pads 302 that are formed into the substrate of the die 301. The bonding pads 302 are also referred to as contact pads and are used for wire bonding the image sensor die 301 to the lead frame 101 of FIG. 1.

The prior art image sensor die 301 of FIGS. 3 and 4 requires the multiple component chip scale package shown in FIGS. 1 and 2. As noted earlier, because of the multiple components required to package this image sensor die 301, the cost is relatively high.

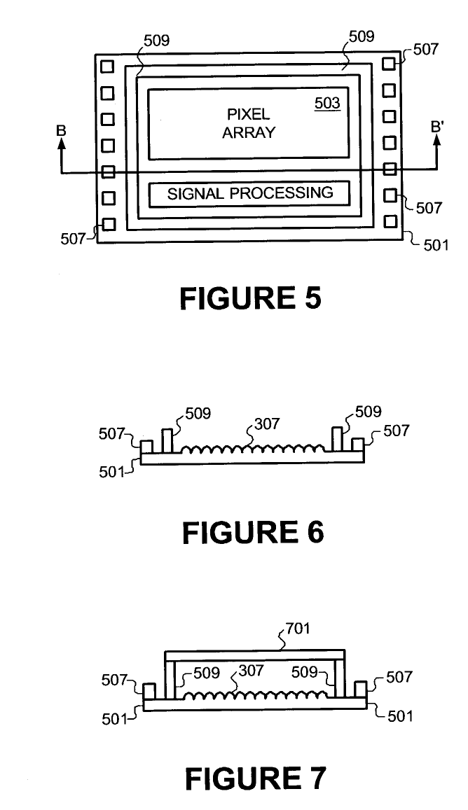

FIGS. 5 and 6 illustrate an image sensor die formed in accordance with the present invention. The core areas of the die 501 remain the same, i.e., the pixel array 503 and the signal processing block remain as in the prior art.

Further, the structure of the pixel area 503, the signal processing block, and other circuit structures are well known in the art. For example, the assignee of the present application, OmniVision Technologies, Inc., is the owner of several patents detailing the formation of an image sensor die, those patents be incorporated by reference in their entirety. The present invention is directed towards modifying those prior art image sensor dies with additional structures in order to more efficiently provide chip scale packaging.

However, additional features are provided that make packaging of the die 501 much simpler. First, instead of contact pads 302, stack bumps 507 are present along the peripheral regions of the die 501.

The stack bumps 507 are typically formed from a conductive material, such as aluminum, tungsten, copper, titanium, or the like. In one embodiment, the stack bumps 507 are formed by a deposition and etch process. However, other methods for forming the stack bumps 507 are suitable. In one embodiment, the stack bumps 507 are raised above the surface of the image sensor die, and typically raised well above the surface of the microlenses 307. The stack bumps 507 serve to propagate signals output by the image sensor die 501 to either a printed circuit board or other packaging system. Therefore, the stack bumps 507 can be directly attached to a printed circuit board, similar to a ball grid array (BGA) connection technique.

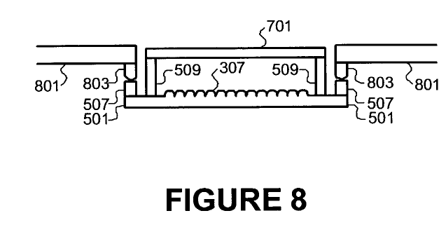

Additionally, a spacer ring 509 is formed around the pixel array 503. The purpose of the spacer ring 509 is to support a glass lid 701 (see FIG. 7) that will form a seal and protect the pixel array 503. The term glass lid as used herein is not limited to a glass material, but refers to any material that is substantially transparent to radiation having a selected wavelength.

In some embodiments, the spacer ring 509 extends around the entire periphery of the image sensor die 501, encompassing nearly all of the circuitry except for the stack bumps 507. In other embodiments, the spacer ring 507 only surrounds the pixel array 503 and the glass lid 701 is sized to coincide with the shape of the spacer ring 509. The material used to form the spacer ring is variable, but preferably should not be a conducting material.

The material to form the spacer ring 509 should be easily formed onto an image sensor die 501 using conventional semiconductor processes. For example, an oxide or other dielectric material may be used. The formation of the spacer ring 509 can be performed using conventional semiconductor techniques including deposition, masking, and etching. Alternatively, the spacer ring 509 can be formed by direct printing or dispensing.

As seen in FIGS. 6 and 7, the spacer ring 509 should extend above the microlenses 307 such that the glass lid 701 is not in contact with the microlenses 307. Although the spacer ring 509 is shown to be taller than the stack bumps 507, in other embodiments, the spacer ring 509 has a lesser height than the stack bumps 507.

Other types of materials suitable for use for the spacer ring 509 are epoxies, polyimides, or resins. The advantage of an epoxy is that the glass lid 701 can be secured directly to the spacer ring 509. The glass lid 701 may be secured to the spacer ring 509 either prior to or after the image sensor die 501 have been diced into individual units out of the wafer. In one embodiment, the glass lid 701 is secured to the individual image sensor die 501 prior to dicing. This has the advantage of minimizing or eliminating particulate contamination of the pixel array during the dicing process.

Turning next to FIG. 8, the image sensor die with glass lid of FIG. 7 can then be further packaged to a printed circuit board or a flexible tape. In FIG. 8, a flexible tape 801 includes connectors 803 that can be electrically attached to the stack bumps 507, by any number of conventional means. Further, although a flexible tape 801 is shown, a printed circuit board can easily be substituted therefore.

Thus, to summarize, the present invention discloses an image sensor die that has structures intended to more efficiently package the image sensor die. The structures include a spacer ring and stack bumps. The spacer ring serves to support a glass lid over the pixel array of the image sensor die. The stack bumbs are raised in order to facilitate direct connection to flexible tape or a printed circuit board.

Further, a method for forming image sensor dies is disclosed. The method comprises forming a plurality of image sensor dies onto a semiconductor wafer. The image sensor die include a spacer ring structure and stack bumps. Glass lids are placed onto the spacer ring to seal and protect the pixel array. The wafer is then diced into individual image sensor die. Following dicing, the individual image sensor die are then packaged further by attaching, through the stack bumps, to a flexible tape or a printed circuit board, or in fact any other type of structural apparatus.

The above description of illustrated embodiments of the invention is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description. The terms used in the following claims should not be construed to limit the invention to the specific embodiments disclosed in the specification and the claims. Rather, the scope of the invention is to be determined entirely by the following claims that are to be construed with accordance with established doctrines of claim interpretation.

What is claimed is:

1. A method comprising:
forming a plurality of image sensor die on a semiconductor wafer, said plurality of image sensor die having a spacer ring surrounding a pixel array on said image sensor die;
placing a glass lid onto said spacer ring, said glass lid being secured to said spacer ring; and
dicing said wafer into individual image sensor die.

2. The method of claim 1 further including forming stack bumps onto said plurality of image sensor die, said stack bumps being raised relative to the surface of said image sensor die.

3. The method of claim 2 further including attaching said image sensor die to a flexible tape or printed circuit board through said stack bumps.

4. The method of claim 2 wherein said spacer ring is formed from a polyimide.

5. The method of claim 2 wherein said spacer ring is formed from a resin or an epoxy.

6. The method of claim 2 wherein said stack bumps are taller than said spacer ring.

7. An image sensor die comprising:
a pixel array;
a signal processing block;
a spacer ring encompassing said pixel array; and
stack bumps that are raised above the surface of said image sensor die.

8. The image sensor die of claim 7 further including a glass lid secured to said spacer ring.

9. The image sensor die of claim 7 wherein said stack bumps are taller than said spacer ring.

10. The image sensor die of claim 7 wherein said spacer ring is formed from a polyimide.

11. The method of claim 7 wherein said spacer ring is formed from a resin or an epoxy.
